(19) United States
(12) Patent Application Publication
(10) Pub. No.: US 2006/0234529 A1
(43) Pub. Date: Oct. 19, 2006

(54) Electrical Connector

(76) Inventors: Hidehisa Yamagami, Kanagawa (JP); Yusuke Mito, Tokyo (JP)

Correspondence Address: BARLEY SNYDER, LLC, 1000 WESTLAKES DRIVE, SUITE 275, BERWYN, PA, 19312, US

(21) Appl. No.: 11/278,971

(22) Filed: Apr. 7, 2006

(30) Foreign Application Priority Data
Apr. 15, 2005 (JP) 2005-117785

(51) Int. Cl. H05K 1/00

(52) U.S. Cl. 439/79

(57) ABSTRACT

An electrical connector comprises an insulating housing and first contacts secured to the housing. Each of the first contacts has the same shape and includes a housing securing member, a contact member extending from a first end of the housing securing member, and a circuit board connecting member extending from a second end of the housing securing member that is offset from the contact member. The first contacts are arranged such that adjacent circuit board connecting members of the first contacts are arranged at substantially the same pitch. A plurality of the first contacts is inverted by substantially 180 degrees, and the contact members of the first contacts inverted by substantially 180 degrees and adjacent contact members of the first contacts not inverted by substantially 180 degrees are arranged at a pitch different from the pitch of the circuit board connecting members.

### FIELD OF THE INVENTION

The invention relates to an electrical connector having a pitch conversion.

### BACKGROUND OF THE INVENTION

An electrical connector having a pitch conversion can be used in cases where a plurality of electronic components are connected to each other, electronic components are connected to a circuit board, circuit boards are connected to each other, or a mating connector having contacts that are connected to a plurality of electrical wires and a circuit board are connected to each other.

FIG. 8 shows an example of a conventional electrical connector 101 (see JP 6-333652A) that is used when a plurality of electronic components are connected to each other. As shown in FIG. 8, the electrical connector 101 includes a wiring board 102. An insulating frame 103 is provided around the wiring board 102. A plurality of first contacts 104 are provided side by side at a specified pitch on a portion of the insulating frame 103 corresponding to a first side of the wiring board 102. A plurality of second contacts 105 are provided side by side at a pitch that is smaller than the specified pitch described above on a portion of the insulating frame 103 corresponding to a side opposite from the first side of the wiring board 102.

A plurality of conductor lines 110 connect the first contacts 104 with the second contacts 105 and are formed on the wiring board 102. External terminals 107 of a first electronic component 106 are inserted into the first contacts 104, and external terminals 109 of a second electronic component 108 are inserted into the second contacts 105 to connect the first and second electronic components 106, 108 via the electrical connector 101.

The electrical connector 101 can be applied to a wide variety of electronic components by varying the pattern of the conductor lines 110 formed on the wiring board 102 and varying the pitch of the first and second contacts 104, 105. Therefore, there is no need to manufacture multiple contact molds according to pitch conversion modes. Thus, the cost of manufacturing the electrical connector 101 can be reduced. However, in the electrical connector 101, it is necessary to provide the wiring board 102 for the purpose of pitch conversion, which adds to the cost of the electrical connector 101. Furthermore, in addition to having to attach the first and second contacts 104, 105 to the insulating frame 103, the wiring board 102 must also be mounted within the insulating frame 103. As a result, the electrical connector 101 is difficult to assemble.

FIG. 7 shows another example of a conventional electrical connector 201 (see JP 6-333652A) that has a pitch conversion. As shown in FIG. 7, the electrical connector 201 includes a plurality of first through fifth contacts 203a, 203b, 203c, 203d, 203e having a large variety of shapes. The first through fifth contacts 203a, 203b, 203c, 203d, 203e are press-fitted to an insulating housing 202. A first electronic component 204 has external terminals 205 extending therefrom. A second electronic component 206 has external terminals 207 extending therefrom

In the electrical connector 201, the first through fifth contacts 203a, 203b, 203c, 203d, 203e each have a different shape. Therefore, in order to perform pitch conversion, different molds need to be manufactured depending upon the number of the external terminals 205, 207. Moreover, when the first through fifth contacts 203a, 203b, 203c, 203d, 203e are press-fitted to the housing 202, the first through fifth contacts 203a, 203b, 203c, 203d, 203e need to be press-fitted from a side of the first electronic component 204 or from the opposite side thereof. However, the amount of offset in each of the first through fifth contacts 203a, 203b, 203c, 203d, 203e is different. The amount of bending generated in each of the first through fifth contacts 203a, 203b, 203c, 203d, 203e during press-fitting therefore is different, which causes problems during press-fitting to the housing 202.

### BRIEF SUMMARY OF THE INVENTION

It is therefore an object of the invention to provide an electrical connector having a pitch conversion in which the cost of the electrical connector is low and the electrical connector can be easily assembled.

This and other objects are achieved by an electrical connector comprising an insulating housing and first contacts secured to the housing. Each of the first contacts has the same shape and includes a housing securing member, a contact member extending from a first end of the housing securing member, and a circuit board connecting member extending from a second end of the housing securing member that is offset from the contact member. The first contacts are arranged such that adjacent circuit board connecting members of the first contacts are arranged at substantially the same pitch. A plurality of the first contacts is inverted by substantially 180 degrees, and the contact members of the first contacts inverted by substantially 180 degrees and adjacent contact members of the first contacts not inverted by substantially 180 degrees are arranged at a pitch different from the pitch of the circuit board connecting members.

### BRIEF DESCRIPTION OF THE DRAWINGS

FIG. 1 is a front view of an electrical connector according to the invention;

FIG. 2 is a plan view of the electrical connector;

FIG. 3 is a partial cross-sectional bottom view of the electrical connector;

FIG. 4 is a sectional view taken along line 4-4 in FIG. 1;

FIG. 5 is an enlarged view of region A in FIG. 3;

FIG. 6 is a side view showing the electrical connector mated with mating connectors;

FIG. 7 is a plan view of an electrical connector of the prior art; and

FIG. 8 is a plan view of another electrical connector of the prior art.

### DETAILED DESCRIPTION OF THE INVENTION

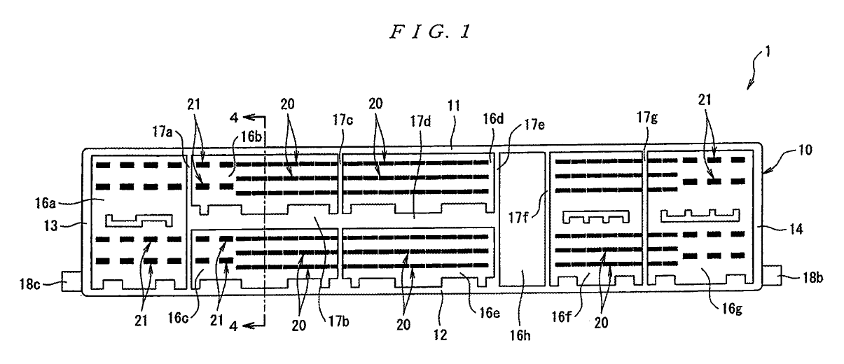

FIG. 1 shows an electrical connector 1. The electrical connector 1 comprises an insulating housing 10. The housing 10 may be formed, for example, from molding an insulating resin. The housing 10 has a substantially rectangular shape and includes a top wall 11, bottom wall 12, first side wall 13, second side wall 14, and rear wall 15. A plurality of first through seventh connector receiving recesses 16a, 16b, 16c, 16d, 16e, 16f, 16g, respectively, are formed in the housing 10.

The first connector receiving recess 16a extends from the first side wall 13 to a first partition wall 17a that extends between the top wall 11 and the bottom wall 12. The second and third connector receiving recesses 16b, 16c extend between the first partition wall 17a and a third partition wall 17c that extends between the top wall 11 and the bottom wall 12. A second partition wall 17b extends between the first and third partition walls 17a, 17c between the second and third connector receiving recesses 16b, 16c. The second connector receiving recess 16b is arranged above the second partition wall 17b, and the third connector receiving recess 16c is arranged beneath the second partition wall 17b. The fourth and fifth connector receiving recesses 16d, 16eextend between the third partition walls 17c and a fifth partition wall 17e that extends between the top wall 11 and the bottom wall 12. A fourth partition wall 17d extends between the third and fifth partition walls 17c, 17e between the fourth and fifth connector receiving recesses 16d, 16e. The fourth connector receiving recess 16d is arranged above the fourth partition wall 17d, and the fifth connector receiving recess 16e is arranged beneath the fourth partition wall 17d. An empty recess 16h extends between the fifth partition wall 17e and a sixth partition wall 17f that extends between the top wall 11 and the bottom wall 12. The sixth connector receiving recess 16f extends between the sixth partition wall 17f and a seventh partition wall 17g that extends between the top wall 11 and the bottom wall 12. The seventh connector receiving recess 16g extends between the seventh partition wall 17g and the second side wall 14.

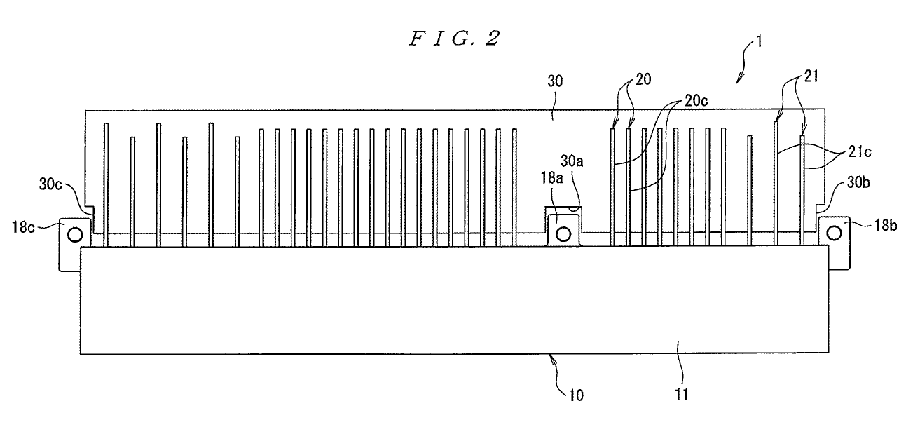

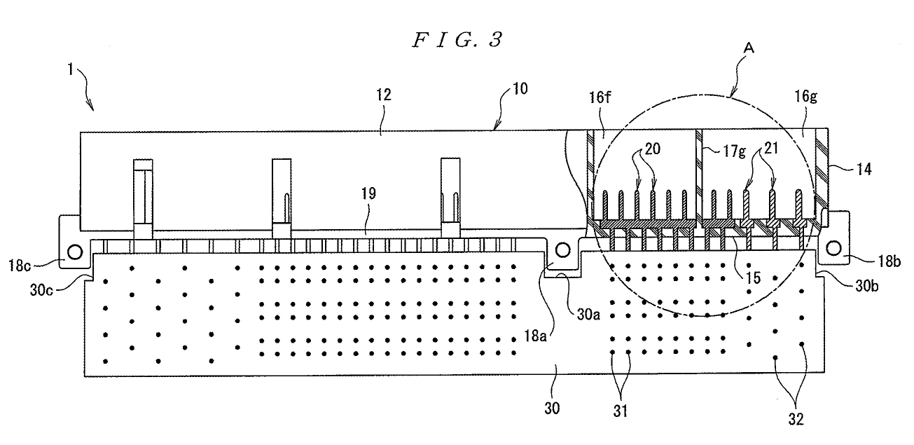

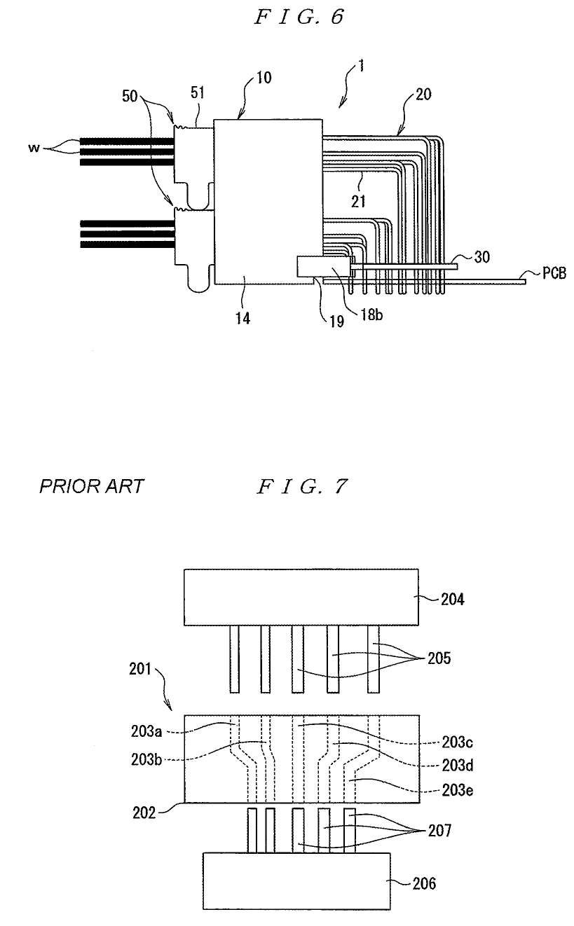

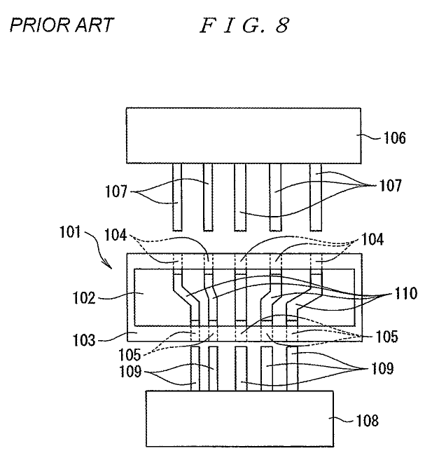

As shown in FIGS. 1-4 and 6, first, second, and third printed circuit board attachment members 18a, 18b, 18c, respectively, are provided on the rear wall 15 of the housing 10. As shown in FIG. 2, the first printed circuit board attachment member 18a protrudes rearward from the rear wall 15 and is positioned toward the right. The second printed circuit board attachment member 18b protrudes rearward from the right end portion of the rear wall 15. The third printed circuit board attachment member 18c protrudes rearward from the left end portion of the rear wall 15. As shown in FIG. 3, a cutout step member 19 for mounting the housing 10 on a printed circuit board PCB (FIG. 6) is formed in a bottom surface of the rear wall 15 of the housing 10. The cutout step member 19 is formed so as to open rearward and downward in the housing 10. The cutout step member 19 has a depth in a vertical direction such that the bottom surface of the printed circuit board PCB (FIG. 6) is in the same plane as a bottom surface of the bottom wall 12 of the housing 10 when the housing 10 is mounted on the printed circuit board PCB (FIG. 6).

The housing 10 contains first and second contacts 20, 21. The first contacts 20 may be, for example, signal contacts. The second contacts 21 may be, for example, power supply contacts. For example, the second contacts 21 may be arranged in four rows in the first connector receiving recess 16aand in two rows in the second connector receiving recess 16b. The first contacts 20 may be arranged in three rows in the second connector receiving recess 16b. The second contacts 21 may be arranged in two rows and the first contacts 20 may be arranged in three rows in the third connector receiving recess 16c as well. The first contacts 20 may be arranged in three rows in the fourth connector receiving recess 16d. The first contacts 20 may be arranged in three rows in the fifth connector receiving recess 16e. The first contacts 20 may be arranged in six rows in the sixth connector receiving recess 16f. The first contacts 20 may be arranged in six rows and the second contacts 21 may be arranged in four rows in the seventh connector receiving recess 16g.

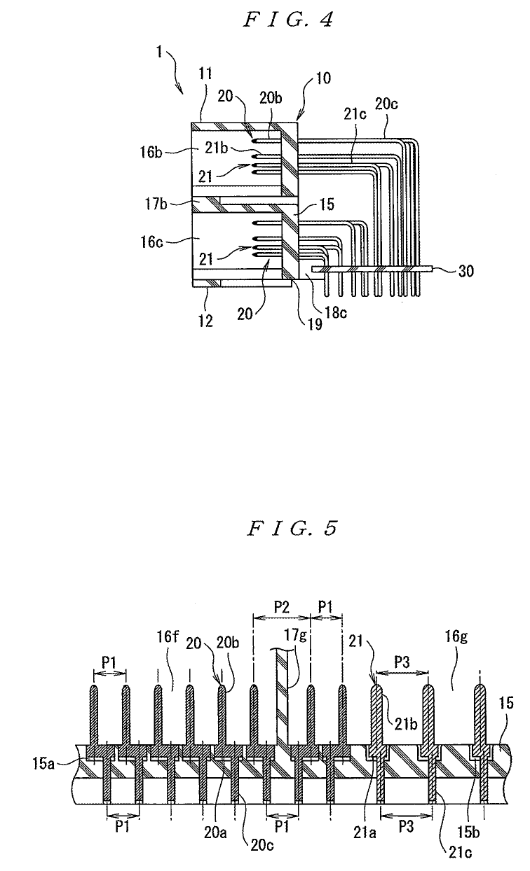

As shown in FIGS. 4-5, each of the first contacts 20 comprises a housing securing member 20a that is press-fitted to a contact securing opening 15a in the rear wall 15 of the housing 10. A contact member 20b extends forward from a front end of the housing securing member 20a. A circuit board connecting member 20c extends rearward from a rear end of the housing securing member 20a and is then bent downward to be connected by soldering to the printed circuit board PCB (FIG. 6). The contact members 20b of the first contacts 20 have a substantially tab-like shape and extend into interiors of the respective second through seventh connector receiving recesses 16b, 16c, 16d, 16e, 16f, 16g so that the contact members 20b are received by and make contact with female type mating contacts (not shown) provided in mating connectors 50 (FIG. 6). As shown in FIG. 5, the first contacts 20 are formed so that center lines of the contact members 20b and center lines of the circuit board connecting members 20c are offset from each other. Each of the first contact 20 may be formed to have the same shape and may be formed, for example, by stamping and forming a metal plate.

As shown in FIGS. 4-5, each of the second contacts 21 comprises a housing securing member 21a that is press-fitted to contact securing openings 15b in the rear wall 15 of the housing 10. A contact member 21b extends forward from a front end of the housing securing member 21a. A circuit board connecting member 21c extends rearward from a rear end of the housing securing member 21a and is then being bent downward for connection to the printed circuit board PCB (FIG. 6), for example, by soldering. The contact members 21b of the second contacts 21 have a substantially tab-like shape that is wider than that of the contact members 20b of the first contacts 20. The contact members 21b extend into the interiors of the respective first, second, third, and seventh connector receiving recesses 16a, 16b, 16c, 16g so that the contact members 21b are received by and make contact with the female type mating contacts (not shown) provided in the mating connectors 50 (FIG. 6). As shown in FIG. 5, the second contacts 21 are formed so that center lines of the contact members 21b and center lines of the circuit board connecting members 21c are offset from each other. Each of the second contacts 21 may be formed to have the same shape and may be formed, for example, by stamping and forming a metal plate.

The first contacts 20 that are disposed in the second through seventh connector receiving recesses 16b, 16c, 16d, 16e, 16f, 16g are arranged so that the circuit board connecting members 20c of adjacent first contacts 20 have substantially the same pitch P1, as shown in FIG. 5 (only the signal contacts arranged in the sixth and seventh connector receiving recesses 16f, 16g are shown in FIG. 5). The first contacts 20 that are disposed in the second, third, and sixth connector receiving recesses 16b, 16c, 16f are arranged so that the contact members 20b are positioned on a left side of the respective circuit board connecting member 20c. The adjacent contact members 20b are arranged to have substantially the same pitch P1 there between. As shown in FIG. 5, the first contacts 20 that are disposed in the fourth, fifth, and seventh connector receiving recesses 16d, 16e, 16g are inverted by substantially 180 degrees. The adjacent contact members 20b of the first contacts 20 that are inverted by substantially 180 degrees have the pitch P1. The contact member 20b of the leftmost first contact 20 of each row among the first contacts 20 that are inverted by substantially 180 degrees and the contact member 20b of the rightmost first contact 20 that is adjacent to this first contact 20 in each row (among the first contacts 20 that are disposed in the second, third, and sixth connector receiving recesses 16b, 16c, 16f) has a pitch P2, which is different from the pitch P1 between the circuit board connecting members 20c.

As shown in FIG. 1, the third partition wall 17c is disposed between the leftmost first contacts 20 of the substantially 180 degree inverted first contacts 20 arranged in the fourth connector receiving recess 16d and the first contacts 20 arranged in the second connector receiving recess 16b that are adjacent to the leftmost first contacts 20. The third partition wall 17c is further disposed between the leftmost first contacts 20 of the substantially 180 degree inverted first contacts 20 arranged in the fifth connector receiving recess 16e and the first contacts 20 arranged in the third connector receiving recess 16c that are adjacent to the leftmost first contacts 20. As shown in FIG. 5, the seventh partition wall 17g is disposed between the leftmost first contacts 20 of the substantially 180 degree inverted first contacts 20 arranged in the seventh connector receiving recess 16g and the first contacts 20 that are arranged in the sixth connector receiving recess 16f that are adjacent to the leftmost first contacts 20.

As shown in FIG. 5, the second contacts 21 that are disposed in the first, second, third, and seventh connector receiving recesses 16a, 16b, 16c, 16g are arranged so that the circuit board connecting members 21c of adjacent second contacts 21 have substantially the same pitch P3 (only the second contacts 21 arranged in the seventh connector receiving recess 16g are shown in FIG. 5). The second contacts 21 are arranged so that the contact members 21b are positioned on the left sides of the circuit board connecting members 21c. The adjacent contact members 21b are arranged to have substantially the same pitch P3 there between.

As shown in FIG. 3, a tine plate 30 for aligning the circuit board connecting members 20c of the first contacts 20 and the circuit board connecting members 21c of the second contacts 21 is attached above the bottom surface of the bottom wall 12 of the housing 10. The height of the housing 10 can be reduced by the thickness of the printed circuit board PCB (FIG. 6) by attaching the tine plate 30 above the bottom surface of the bottom wall 12 of the housing 10 and making the bottom surface of the printed circuit board PCB (FIG. 6) in the same plane as the bottom surface of the bottom wall 12 of the housing 10. A plurality of alignment openings 31, 32 for insertion and alignment of the circuit board connecting members 20c, 21c of the first and second contacts 20, 21, respectively, is formed in the tine plate 30. A first cutout 30a with which the first printed circuit board attachment member 18a engages, a second cutout 30b with which the second printed circuit board attachment member 18b engages, and a third cutout 30c with which the third printed circuit board attachment member 18c engages are formed in the tine plate 30. Movement of the tine plate 30 in the left-right direction is thereby restricted by the first, second, and third printed circuit board attachment members 18a, 18b, 18c and cutouts 30a, 30b, 30c working together.

As shown in FIG. 6, mating housings 51 of the mating connectors 50 are received in the first through seventh connector receiving recesses 16a, 16b, 16c, 16d, 16e, 16f, 16g of the electrical connector 1 during mating. The mating contacts (not shown), which are connected to electrical wires W, are accommodated in the mating housings 51 of the mating connectors 50. When the electrical connector 1 and the mating connectors 50 are mated, the mating contacts (not shown) come into contact with the first and second contacts 20, 21 of the housing 10 to electrically connect the electrical wires W with the printed circuit board PCB.

Due to the arrangement of the first contacts 20 in the electrical connector 1, pitch conversion can be performed by using only one type of the first contacts 20. Additionally, pitch conversion does not need to be performed for the second contacts 21. Consequently, it is not necessary to use a wiring board or the like in addition to the first contacts 20 for the purpose of pitch conversion. As a result, the cost of the electrical connector 1 is low, and the electrical connector 1 can be easily assembled. Furthermore, since there is no need to use contacts having a large variety of shapes for the purpose of pitch conversion, it is likewise unnecessary to manufacture many contact molds according to the pitch conversion modes. Problems associated with press-fitting the first and second contacts 20, 21 to the housing 10 are also eliminated.

In addition, due to the arrangement of the first through seventh partition walls 17a, 17b, 17c, 17d, 17e, 17f, 17g, it is possible to form second through fifth connector receiving recesses 16b, 16c, 16d, 16e that can receive separate mating connectors 50 on either side of the third partition wall 17c. Furthermore, it is possible to form sixth through seventh connector receiving recesses 16f, 16g that can receive separate mating connectors 50 on either side of the seventh partition wall 17g. Consequently, even in cases where the electrical connector 1 is a multi-pole connector provided with numerous first and second contacts 20, 21, separate mating connectors 50 can easily be mated with the electrical connector 1 without installing any power step-up mechanism or the like.

The foregoing illustrates some of the possibilities for practicing the invention. Many other embodiments are possible within the scope and spirit of the invention. For example, the substantially 180 degree inverted first contacts 20 are not limited to the first contacts 20 that are disposed in the fourth, fifth, and seventh connector receiving recesses 16d, 16e, 16g, as long as the first contacts 20 are inverted substantially 180 degrees and the pitch between the contact members 20b of the first contacts 20 and the contact members 20b of the first contacts 20 that are adjacent to these first contacts 20 is different from the pitch between the circuit board connecting members 20c. It is also possible to perform pitch conversion by inverting a plurality of the second contacts 21 substantially 180 degrees. Moreover, the connector receiving recesses are not limited to the first through seventh connector receiving recesses 16a, 16b, 16c, 16d, 16e, 16f, 16g and can be altered as appropriate. In addition, the number of the first and second contacts 20, 21 arranged in the first through seventh connector receiving recesses 16a, 16b, 16c, 16d, 16e, 16f, 16g may be varied. It is, therefore, intended that the foregoing description be regarded as illustrative rather than limiting, and that the scope of the invention is given by the appended claims together with their full range of equivalents.

What is claimed is:

1. An electrical connector, comprising:
an insulating housing;
first contacts secured to the housing, each of the first contacts having the same shape and including a housing securing member, a contact member extending from a first end of the housing securing member, and a circuit board connecting member extending from a second end of the housing securing member that is offset from the contact member; and
the first contacts being arranged such that adjacent circuit board connecting members of the first contacts are arranged at substantially the same pitch, a plurality of the first contacts is inverted by substantially 180 degrees, and the contact members of the first contacts inverted by substantially 180 degrees and adjacent contact members of the first contacts not inverted by substantially 180 degrees are arranged at a pitch different from the pitch of the circuit board connecting members.

2. The electrical connector according to claim 1, wherein a partition wall extends between the first contacts not inverted by substantially 180 degrees and the first contacts inverted by substantially 180 degrees.

3. The electrical connector according to claim 1, wherein a center line of the contact member is offset from a center line of the circuit board connecting member.

4. The electrical connector according to claim 1, wherein the first contacts are formed from a metal plate.

5. The electrical connector according to claim 1, wherein the housing connecting member is press-fitted into the housing.

6. The electrical connector according to claim 1, further comprising second contacts.

7. The electrical connector according to claim 6, wherein the first contacts are signal contacts and the second contacts are power supply contacts.

8. The electrical connector according to claim 6, wherein the second contacts have contact members, the contacts members of adjacent second contacts being arranged at a pitch different from the pitch of the first contacts.
